(19) United States
(12) Patent Application Publication
(10) Pub. No.: US 2025/0085348 A1
(43) Pub. Date: Mar. 13, 2025

(54) INFORMATION PROCESSING DEVICE, DISPLAY AND INPUT DEVICE, AND PROGRAM

(71) Applicant: Tokyo Electron Limited, Tokyo (JP)

(72) Inventor: Kazunari ISHII, Yamanashi (JP)

(21) Appl. No.: 18/956,642

(22) Filed: Nov. 22, 2024

Related U.S. Application Data
(63) Continuation of application No. PCT/JP2023/019133, filed on May 23, 2023.

(30) Foreign Application Priority Data
Jun. 6, 2022 (JP) 2022-091873

(51) Int. Cl. G01R 31/319; G01R 31/28

(52) U.S. Cl. CPC G01R 31/31912; G01R 31/2891

(57) ABSTRACT

With respect to an information processing device for setting polishing content of probes configured to contact devices under test, the information processing device includes a processor; and a memory storing program instructions that cause the processor to set a polishing area in a polishing member configured to polish the probes; set an operation pattern to be used during the polishing of the probes; and calculate a relative trajectory between the polishing member and the probes based on the set polishing area and the set operation pattern.

### CROSS-REFERENCE TO RELATED APPLICATIONS

This application is a continuation application of International Application No. PCT/JP2023/019133 filed on May 23, 2023, and designating the U.S., which is based upon and claims priority to Japanese Application No. 2022-091873, filed on Jun. 6, 2022, the entire contents of which are incorporated herein by reference.

### BACKGROUND

### 1. Technical Field

The present disclosure relates to an information processing device, a display and input device, and a program.

### 2. Description of the Related Art

Patent Document 1 discloses a polishing method for polishing the pin tips of multiple probes that come into contact with a device under test, such as a wafer, during testing in a test device (a prober device) configured to perform an electrical test of the device under test.

In the polishing of the probe, with respect to a form of the polishing member (for example, the size and layout of a polishing stone) and an operation during the polishing (for example, an operation pattern of the polishing member), requested content is different for each user who uses the test device. In the related art, based on the requested content of each user, a device is designed individually at the time of manufacturing or setting the test device, and is provided for performing polishing according to polishing content for each user.

### RELATED ART DOCUMENT

### Patent Document

Patent Document 1: Japanese Laid-Open Patent Application Publication No. 2010-48789

### SUMMARY

According to an aspect of the present disclosure, with respect to an information processing device for setting polishing content of probes configured to contact devices under test, the information processing device includes a processor; and a memory storing program instructions that cause the processor to set a polishing area in a polishing member configured to polish the probes; set an operation pattern to be used during the polishing of the probes; and calculate a relative trajectory between the polishing member and the probes based on the set polishing area and the set operation pattern.

### BRIEF DESCRIPTION OF THE DRAWINGS

FIG. 1 is a schematic explanatory diagram illustrating an overall configuration of a test device and a setting computer according to an embodiment;

FIG. 2 is a block diagram illustrating an overall configuration of a processing system including the test device;

FIG. 3 is a block diagram illustrating a hardware configuration of a control device and the setting computer;

FIG. 4 is a block diagram illustrating functional blocks for setting polishing content in the setting computer;

FIG. 5 is a view illustrating a main screen for setting the polishing content;

FIG. 6A is a view illustrating a polishing medium selection button;

FIG. 6B is a view illustrating a size input screen;

FIG. 6C is a view illustrating another size input screen;

FIG. 7A is a view illustrating an installation number selection button;

FIG. 7B is a view illustrating a conductive area selection button;

FIG. 7C is a view illustrating a multi-area input screen;

FIG. 8A is a view illustrating another multi-area input screen;

FIG. 8B is a first view illustrating still another multi-area input screen;

FIG. 8C is a second view illustrating still another multi-area input screen;

FIG. 9 is a view schematically illustrating a display of a setting input screen and a pattern setting screen in accordance with an operation of a display screen;

FIG. 10 is a view illustrating the setting input screen;

FIG. 11A is a plan view schematically illustrating a shift between a polishing member and probes;

FIG. 11B is a plan view schematically illustrating a state where the polishing member and the probes are caused to match each other by movement based on an index amount;

FIG. 12A is a view illustrating a pattern selection button;

FIG. 12B is a view illustrating a pattern setting screen;

FIG. 13A is a first diagram illustrating a free pattern setting screen;

FIG. 13B is a second diagram illustrating the free pattern setting screen;

FIG. 14A is a diagram schematically illustrating a setting of multiple frames in a simulation;

FIG. 14B is a diagram schematically illustrating a use range of the polishing member in the simulation;

FIG. 15 is a first view illustrating a display of a main screen during the simulation;

FIG. 16 is a second view illustrating the display of the main screen during the simulation;

FIG. 17A is a diagram schematically illustrating multiple frames and a polishing area in the simulation; and

FIG. 17B is a diagram schematically illustrating multiple plots and the polishing area in the simulation.

### DETAILED DESCRIPTION

In the following, embodiments of the present disclosure will be described with reference to the drawings. In the drawings, the same components are denoted by the same reference symbols, and a duplicate description thereof may be omitted.

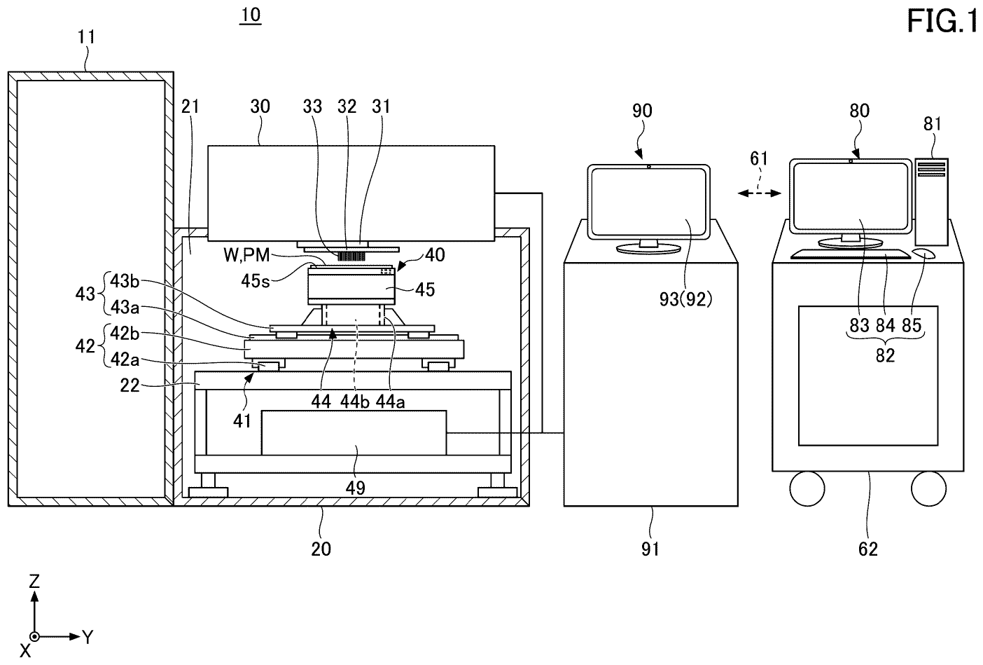

As illustrated in FIG. 1, an information processing device according to the embodiment is configured as a setting computer 80 that is connected to a test device 10 configured to polish multiple probes 33 (test pins) used in a test and that sets polishing content. In the following description, a configuration of the test device 10 will be described first, in order to facilitate understanding of the operation of the probes 33 during polishing.

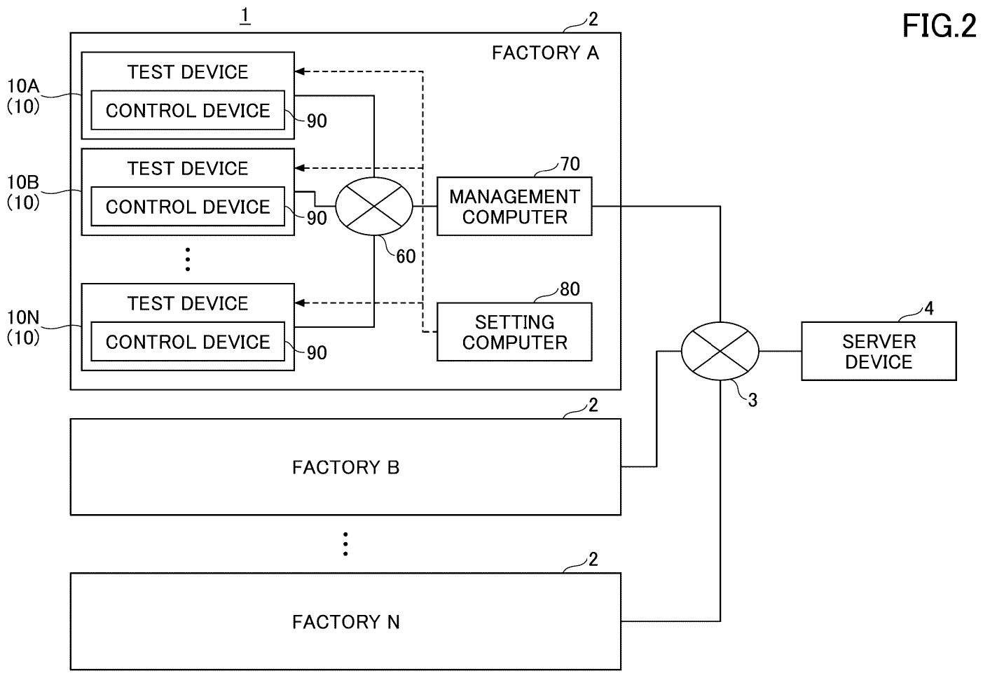

The test device 10 according to the present embodiment is installed in, for example, a factory that manufactures a wafer W, which is an example of a substrate (see also FIG. 2), and performs an electrical test of the manufactured wafer W. Multiple semiconductor devices (LSI, a semiconductor memory, and the like), which are devices under test (DUTs) to be in contact with the probes 33, are formed on the surface of the wafer W. In the electrical test, the presence or absence of abnormality in the semiconductor device, electrical characteristics, and the like are tested. Here, the substrate is not limited to the wafer W, and may be a carrier, a glass substrate, a single chip, an electronic circuit board, or the like on which a semiconductor device is disposed.

The test device 10 includes a loader 11 configured to transfer the wafer W, a housing 20 disposed adjacent to the loader 11, a tester 30 disposed on the upper side of the housing 20, a stage 40 accommodated in the housing 20, and a control device 90 configured to control each component of the test device 10.

The loader 11 takes out the wafer W from a front opening unified pod (FOUP), which is not illustrated, and mounts the wafer W on the stage 40 that has moved within the housing 20. Additionally, the loader 11 takes out the tested wafer W from the stage 40 and accommodates the wafer W in the FOUP.

The housing 20 is formed in a substantially rectangular box shape and has a test space 21 for testing the wafer W therein. The stage 40 for transferring the wafer W is installed on the lower side of the test space 21. In the test space 21, the wafer W mounted on the stage 40 from the loader 11 moves in three-dimensional directions (the X-axis direction, the Y-axis direction, and the Z-axis direction) by the operation of the stage 40.

A probe card 32 is held in an upper portion of the housing 20 via an interface 31. The interface 31 includes a performance board and a large number of connection terminals, which are not illustrated, and is electrically connected to the tester 30 via a test head, which is not illustrated. The tester 30 is connected to the control device 90 of the test device 10 and tests the wafer W under the command of the control device 90.

The probe card 32 includes multiple probes 33 protruding downward in the test space 21. In the test of the test device 10, each of the probes 33 comes into contact with a pad or a solder bump of the DUT of the wafer W that has been moved to an appropriate three-dimensional coordinate position by the stage 40. With this, appropriate circuits formed on one or more test boards (not illustrated) of the tester 30 are electrically connected to the DUTs of the wafer W. In this conductive state, the tester 30 performs an electrical test on the DUTs that are in contact with the probes 33.

The stage 40 is provided in the housing 20 and transfers the wafer W or the probe card 32 in the test space 21. For example, the stage 40 brings the wafer W into contact with the multiple probes 33 by transferring the wafer W from the loader 11 to a position facing the probe card 32 and raising the wafer W toward the probe card 32. After the test, the stage 40 lowers the tested wafer W from the probe card 32 and further transfers the wafer W toward the loader 11.

Specifically, the stage 40 includes a mover 41 (an X-axis movement mechanism 42, a Y-axis movement mechanism 43, and a Z-axis movement mechanism 44) that is movable in the X-axis direction, the Y-axis direction, and the Z-axis direction, a mounting table 45, and a stage controller 49. Additionally, the housing 20 includes a frame structure 22 that supports the mover 41 and the mounting table 45 of the stage 40 and the stage controller 49 in two stages, that is, upper and lower stages. Here, the mover 41 may have a configuration to rotate the mounting table 45 around an axis (in a 0 direction) in addition to moving the mounting table 45 in the X-axis direction, the Y-axis direction, and the Z-axis direction.

The X-axis movement mechanism 42 of the mover 41 includes multiple guide rails 42a fixed to the upper surface of the frame structure 22 and extending along the X-axis direction, and an X-axis movable body 42b disposed between the guide rails 42a. The X-axis movable body 42b includes an X-axis actuator (a motor, a gear mechanism, or the like), which is not illustrated therein, and the X-axis actuator is connected to the stage controller 49. The X-axis movable body 42b reciprocates in the X-axis direction based on the power supply from a motor driver, which is not illustrated, of the stage controller 49.

Similarly, the Y-axis movement mechanism 43 includes multiple guide rails 43a fixed to the upper surface of the X-axis movable body 42b and extending along the Y-axis direction, and a Y-axis movable body 43b disposed between the guide rails 43a. The Y-axis movable body 43b includes a Y-axis actuator (a motor, a gear mechanism, or the like), which is not illustrated, therein, and the Y-axis actuator is connected to the stage controller 49. The Y-axis movable body 43b reciprocates in the Y-axis direction based on the power supply from a motor driver, which is not illustrated, of the stage controller 49.

The Z-axis movement mechanism 44 includes a fixed body 44a installed on the Y-axis movable body 43b and a Z-axis movable body 44b relatively raised and lowered along the Z-axis direction with respect to the fixed body 44a, and holds the mounting table 45 at the upper portion of the Z-axis movable body 44b. The Z-axis movement mechanism 44 includes a Z-axis actuator (a motor, a gear mechanism, or the like), which is not illustrated, and the Z-axis actuator is connected to the stage controller 49. The Z-axis movable body 44b is displaced in the Z-axis direction (the vertical direction) based on power supply from a motor driver, which is not illustrated, of the stage controller 49, and accordingly, the wafer W held on the mounting table 45 is raised and lowered.

The mounting table 45 is a device on which the wafer W is directly mounted, and holds the wafer W on a mounting surface 45s by an appropriate holding means. For example, when the wafer W is held by vacuum suction, the holding means includes a suction passage for suction in the mounting table 45, and a pipe connected to the suction passage and a suction pump are provided at appropriate positions.

The stage controller 49 is connected to the control device 90 and controls the operation of the stage 40 based on a command from the control device 90. The stage controller 49 includes an integrated controller configured to control the operation of the entire stage 40, a PLC or a motor driver for controlling the operation of the mover 41, an illumination controller, a power supply unit, and the like (none of which are illustrated).

A general-purpose computer including a controller 91 configured to control the entire test device 10 and a display and input device 92 (a user interface) connected to the controller 91 can be applied as the control device 90.

The test device 10 configured as described above performs an electrical test of the wafer W under the control of the control device 90. First, the test device 10 transmits, to the stage controller 49, a command to move the loader 11 and the stage 40, delivers the wafer W from the loader 11 to the mounting table 45, and transfers the wafer W in the test space 21. At this time, the stage controller 49 moves the mounting table 45 in the horizontal direction by the X-axis movement mechanism 42 and the Y-axis movement mechanism 43 to cause the contact position of the wafer W to face each of the probes 33, and then raises the mounting table 45 along the vertical direction (the Z-axis direction) by the Z-axis movement mechanism 44.

When the mounting table 45 is raised, the probes 33 come into contact with the wafer W, so that the tester 30 and the wafer W are electrically connected to each other. Subsequently, the tester 30 transmits an electric signal from the test head to each of the DUTs of the wafer W, receives a device signal as a response from each of the DUTs, and determines the presence or absence of abnormality, electric characteristics, and the like of each of the DUTs. Additionally, the test device 10 sequentially repeats the test of the DUTs while shifting the position on the wafer W by moving in the X-axis direction, the Y-axis direction, and the Z-axis direction by the stage 40, thereby testing all the DUTs.

After the test of all the DUTs, the test device 10 lowers the mounting table 45 to separate the wafer W from the probes 33, and transfers the wafer W to the loader 11. The loader 11 receives the tested wafer W from the stage 40 and accommodates the wafer W in the FOUP.

Additionally, in the test device 10 according to the present embodiment, a foreign substance may adhere to a portion of the probe 33 or the probe 33 may be partially worn out in the test. Therefore, when the test device 10 is under maintenance, as described above, a probe polishing process of polishing each of the probes 33 of the probe card 32 is performed. For example, in the probe polishing process, the user disposes a polishing member PM on the mounting surface 45s of the stage 40. The control device 90 operates the stage 40 including the polishing member PM based on a recipe (the polishing content) of the probe polishing process. The polishing member PM can polish each of the probes 33 by moving in the horizontal direction (the X-axis direction and the Y-axis direction) relative to each of the probes 33 after contacting the probe 33 in accordance with the operation of the stage 40.

A processing system 1 including the test device 10 described above allows the user to suitably set the polishing content of the probe polishing process for polishing each of the probes 33. Next, the processing system 1 including the test device 10 will be described with reference to FIG. 2, and the setting of the probe polishing process in the processing system 1 will be described in detail.

The processing system 1 according to the embodiment includes multiple factories 2 each including one or more test devices 10, an external network 3, such as the Internet, connected to each of the factories 2, and a server device 4 connected via the external network 3.

As described above, the factory 2 is a manufacturing site or the like where the wafer W is manufactured, and the test device 10 is installed so that the manufactured wafer W can be immediately tested. The server device 4 is a computer configured to comprehensively manage the manufacturing status of the wafers W in the multiple factories 2, the states of the installed devices, and the like. A computer owned by the user can be applied as the server device 4. Alternatively, the server device 4 may be a computer on the provider side of the test device 10. Here, the processing system 1 may be configured to include only one factory 2, or may be configured to include neither the external network 3 nor the server device 4.

In the factory 2, in addition to the multiple test devices 10, an internal network 60, such as a LAN connected to each of the multiple test devices 10 and a management computer 70 connected to each of the test devices 10 via the internal network 60 are provided. Additionally, the processing system 1 includes the setting computer 80 for setting functions of various devices installed in the factory 2. In the present embodiment, as described above, the setting computer 80 sets the polishing content of the probe polishing process of the test device 10, and transmits the information to the control device 90.

Here, the setting of the polishing content of the probe polishing process may be performed by using the management computer 70 communicably connected to the test device 10. Alternatively, the processing system 1 may be configured to set the polishing content at the server device 4 communicably connected to the factory 2 and transmit the polishing content to the control device 90 of the test device 10. Additionally, the polishing content can be set in the control device 90 itself of the test device 10. In other words, any of the server device 4, the management computer 70, the setting computer 80, or the control device 90 may be used as the information processing device that sets the polishing content of the test device 10.

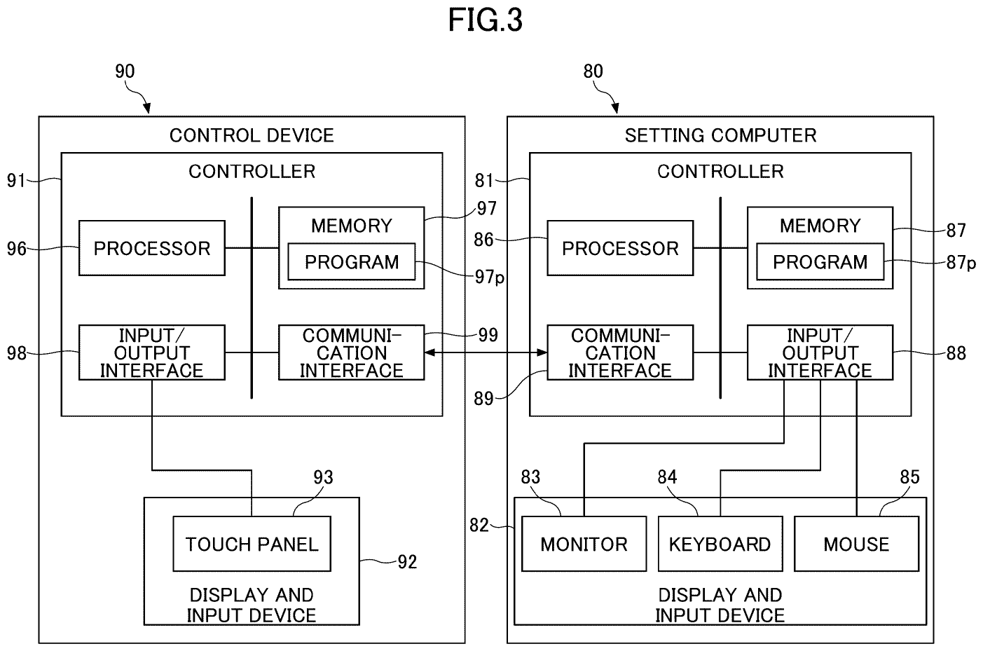

As illustrated in FIG. 1 and FIG. 3, the setting computer 80 according to the present embodiment is detachably connected to the control device 90 of the test device 10 by a communication line 61, and performs information communication with the control device 90. The setting computer 80 is, for example, mounted on a carriage 62 or the like, and can freely move in the factory 2. With this, even when multiple test devices 10A, 10B, . . . , 10N are installed in the factory 2, the user can perform the setting for each of the test devices 10 by using one setting computer 80. Here, the setting computer 80 may be communicably connected to the control device 90 by a communication means, such as a wireless LAN, instead of the communication line 61.

The controller 91 of the control device 90 includes one or more processors 96, a memory 97, an input/output interface 98, a communication interface 99, and an electronic circuit, which is not illustrated. The processor 96 is one or a combination of a central processing unit (CPU), a graphics processing unit (GPU), an application specific integrated circuit (ASIC), a field-programmable gate array (FPGA), a circuit including multiple discrete semiconductors, and the like. The memory 97 is a combination of a volatile memory and a nonvolatile memory (for example, a compact disc, a digital versatile disc (DVD), a hard disk, a flash memory, and the like) as appropriate. The processor 96 controls the operation of the test device 10 by reading and executing a program 97p stored in the memory 97.

With respect to the above, as the display and input device 92 of the control device 90, a touch panel 93 that can visualize and display the operation status of the test device 10 and allow the user to perform an input operation can be applied. Alternatively, the display and input device 92 is not limited to the touch panel 93, and a monitor, a keyboard, a mouse, and the like may be applied.

The setting computer 80 may have substantially the same configuration as the control device 90. That is, as the setting computer 80, a general-purpose computer including a controller 81 and a display and input device 82 connected to the controller 81 can be applied.

The display and input device 82 of the setting computer 80 is configured to include a monitor 83, a keyboard 84, a mouse 85, and the like. Additionally, a device having a touch panel can also be applied as the display and input device 82. The controller 81 of the setting computer 80 includes one or more processors 86, a memory 87, an input/output interface 88, a communication interface 89, and an electronic circuit, which is not illustrated, similarly to the controller 91. The processor 86 reads and executes a program 87p (an application) stored in the memory 87 to internally construct functional units for setting the polishing content of the probe polishing process.

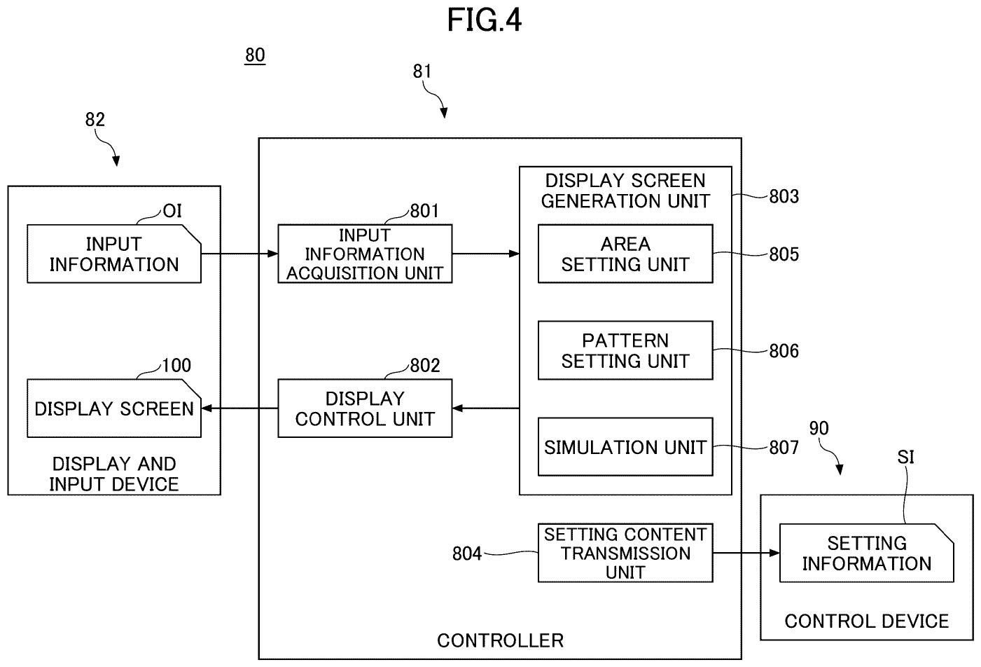

As illustrated in FIG. 4, an input information acquisition unit 801, a display control unit 802, a display screen generation unit 803, a setting content transmission unit 804, and the like are formed in the controller 81. The input information acquisition unit 801 receives user operation content (input information OI) on the display and input device 82, and transmits the input information OI to the display screen generation unit 803. The display control unit 802 transmits, to the display and input device 82, information on a display screen 100 generated by the display screen generation unit 803, and causes the display and input device 82 to display the display screen 100.

The display screen generation unit 803 performs appropriate processing based on the input information OI, generates the display screen 100 corresponding to the operation, and stores the input information OI necessary for the polishing content of the probe polishing process in the memory 87. With respect to the above, the setting content transmission unit 804 generates setting information SI that can be transmitted to the test device 10 after the polishing content is set by the user. The setting content transmission unit 804 monitors the connection between the setting computer 80 and the test device 10, and transmits the setting information SI to the control device 90 based on the user's operation while in a state of connection with the test device 10.

Specifically, an area setting unit 805, a pattern setting unit 806, and a simulation unit 807 are constructed inside the display screen generation unit 803. The functions of the respective units will be described in detail below together with various display screens 100 displayed on the monitor 83 of the display and input device 82 by the controller 81.

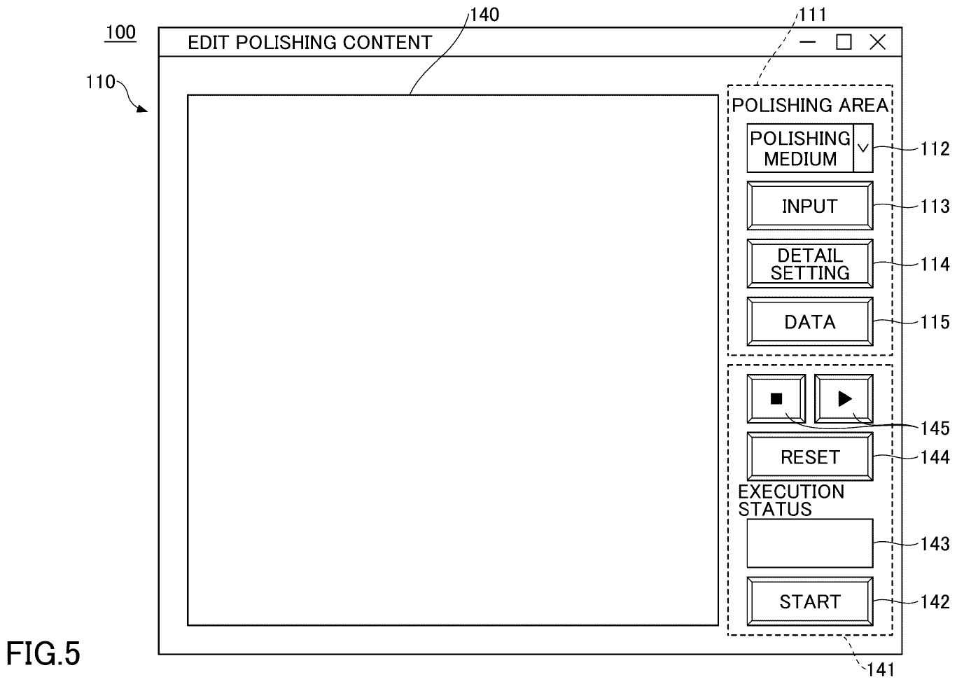

The display screen generation unit 803 generates a main screen 110 indicating editing of the polishing content as illustrated in FIG. 5, as the display screen 100, when the setting of the polishing content is started (when the program 87p is activated). The main screen 110 includes an area setting display group 111 for setting a polishing area of the probe 33, a simulation display group 141 for simulating the set polishing content, and a simulation display screen 140 for displaying a result of the simulation.

The simulation display screen 140 is provided in 70% of the main screen 110 according to the present embodiment, which includes the central portion from the left side of the main screen 110, in order to make it easy for the user to visually recognize the result of the simulation. The main screen 110 arranges the area setting display group 111 on the right and upper side of the simulation display screen 140, and the simulation display group 141 on the right and lower side of the simulation display screen 140.

The area setting display group 111 includes multiple button images for the user to perform a predetermined operation. The multiple button images include, for example, a polishing medium selection button 112, an input button 113, a detail setting button 114, and a data button 115. The polishing medium selection button 112 is a button for the user to set the polishing member PM used to polish the probe 33. The input button 113 is a button for the user to set the polishing area of the polishing member PM in more detail. The detail setting button 114 is a button for changing various settings of the application for editing the polishing. The data button 115 is a button for displaying a history of the polishing content set in the past and reading the past polishing content that is selected by the user.

When receiving that the polishing medium selection button 112 has been pressed by the user as the input information OI, the display screen generation unit 803 causes the area setting unit 805 to operate. The area setting unit 805 displays multiple types of polishing members PM and allows the user to select the polishing member PM.

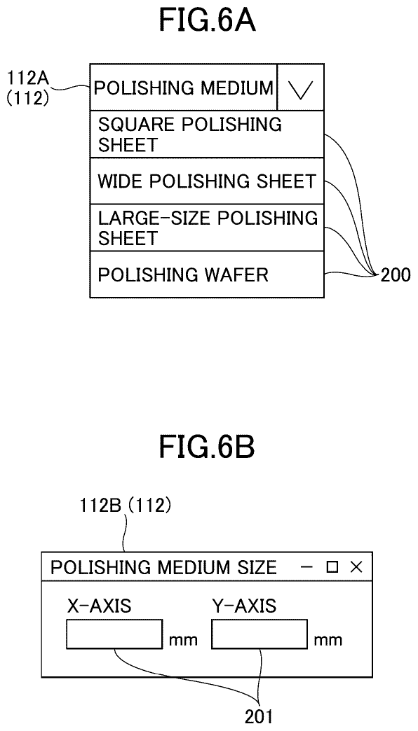

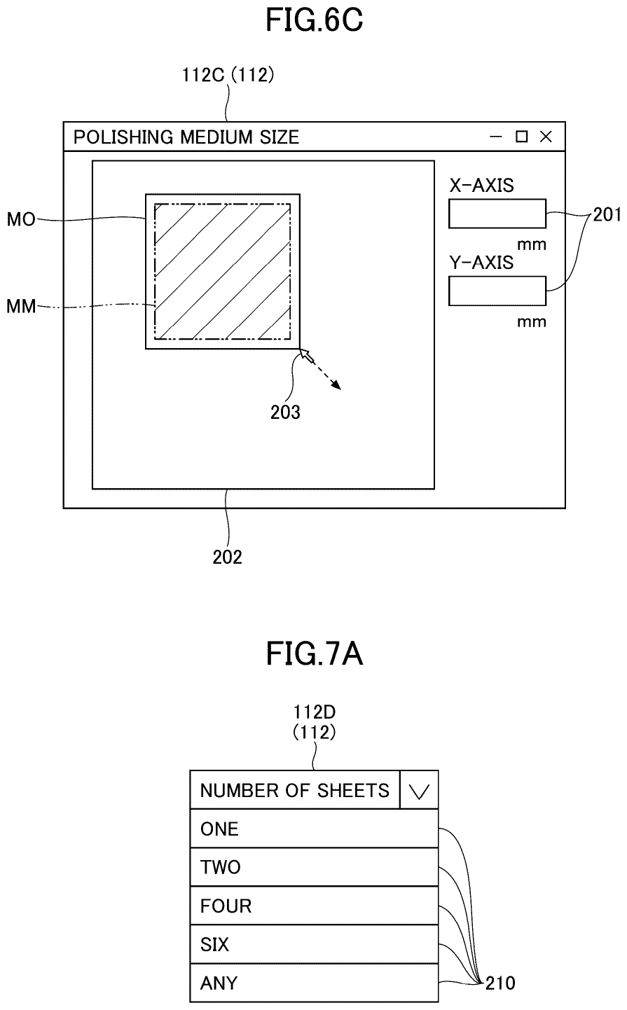

The polishing medium selection button 112 can display a pull-down screen 112A including multiple pull-down options 200, for example, as illustrated in FIG. 6A. Alternatively, the polishing medium selection button 112 may be configured to pop-up display another image indicating multiple types of polishing members PM when the user presses the polishing medium selection button 112. The pull-down screen 112A displays, as the options 200, a list of multiple types of polishing members PM that can be disposed on the mounting surface 45s of the stage 40 and that are commercially available.

The examples of the multiple types of polishing members PM include a square polishing sheet, a wide polishing sheet, a large polishing sheet, a polishing wafer, and the like. The wide polishing sheet is a sheet formed in a rectangular shape and having a long side longer than one side of the square polishing sheet. The large polishing sheet is a rectangular sheet that is larger than the square polishing sheet. The polishing wafer is a polishing stone formed in a wafer shape or a dummy wafer to which a polishing stone is applied. Here, the test device 10 may be configured to include a prober (not illustrated) including a polishing stone for polishing, which is a device different from the stage 40, in addition to the polishing member PM disposed on the stage 40, and to polish each of the probes 33 by operating the prober in the same manner as the stage 40. In this case, the area setting unit 805 may be configured so that a polishing stone installed in the prober is selectable as the polishing member PM.

The area setting unit 805 automatically sets the size of the polishing member PM stored in advance together with the information on the polishing member PM in accordance with the selection of the polishing member PM by the user. However, the size of the polishing member PM can be suitably changed by the user when the polishing member PM is disposed on the mounting surface 45s. Therefore, the area setting unit 805 may be configured to allow the user to input the size of the polishing member PM. For example, as illustrated in FIG. 6B, the area setting unit 805 may display a size input screen 112B (an area setting screen) on which the user can input the size of the polishing member PM as a numerical value. The size input screen 112B includes multiple input fields 201 for inputting the X-axis size and the Y-axis size of the planar shape of the polishing member PM in the horizontal direction.

As illustrated in FIG. 6C, the area setting unit 805 may display a size input screen 112C (the area setting screen) on which the size of the polishing member PM can be input by a drag-and-drop operation of the mouse 85 by the user. For example, the size input screen 112C includes an operation screen 202 for performing a drag-and-drop operation and an input field 201 in which the X-axis size and the Y-axis size of the polishing member PM can be input, in the horizontal direction of the operation screen 202. The input field 201 may be configured to automatically display the X-axis size and the Y-axis size in response to a drag-and-drop operation, in addition to the manual input by the user.

The operation screen 202 displays the square polishing member PM when the user performs a drag-and-drop operation by arranging a pointer 203, which is operated in conjunction with the operation of the mouse 85, at an appropriate position. Here, the drag-and-drop operation in the present specification is not limited to the operation of continuing the click and moving, and then releasing the click by the mouse 85. For example, when a touch panel is used as the display and input device 82, the operation may be an operation of touching the panel, and then sliding on the panel and releasing the touch. In this case, the drag point and the drop point may be set using mechanical buttons. In short, the drag-and-drop operation may be various user operations that allow the user to freely specify a range on the display screen in the input of the information processing device.

When setting the size of the polishing member PM (the polishing area), the area setting unit 805 may set an outer edge MO of the polishing member PM, and additionally may set an effective range MM of actual polishing in the polishing member PM inside the outer edge MO. Here, the area setting unit 805 may set the outer edge MO and the effective range MM of the polishing member PM by one drag-and-drop operation or by separate drag-and-drop operations. Additionally, the shape of the polishing member PM formed on the operation screen 202 is not limited to a square shape, and it is preferable that the shape can be changed to a circular shape, another polygonal shape, or the like by performing an appropriate selection operation.

Further, when a polishing sheet, which is the polishing member PM, is attached to the mounting surface 45s, for example, the area setting unit 805 may be configured to set the number of the polishing sheets, the conductive area, and the like. In the probe polishing process, by using multiple polishing members PM, for example, the polishing can be performed for different purposes such as roughly polishing the probe 33 first and then finely polishing the probe 33.

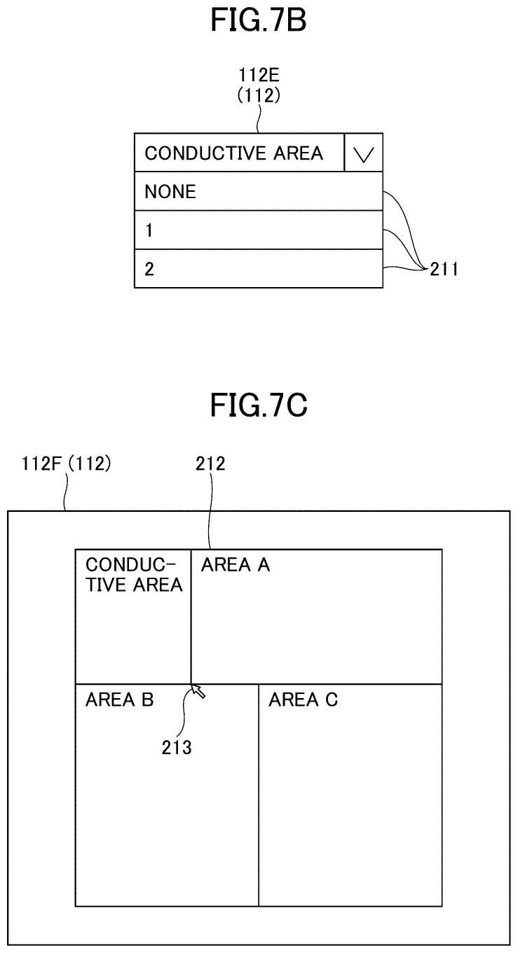

In order to set the number of the polishing members PM, the area setting unit 805 may display an installation number selection button 112D including multiple pull-down options 210 as illustrated in FIG. 7A. Similarly, as illustrated in FIG. 7B, the area setting unit 805 may display a conductive area selection button 112E including multiple pull-down options 211 for setting the number of the conductive areas (none when the number is zero). For example, the installation number selection button 112D and the conductive area selection button 112E may be located on the main screen 110 or a setting input screen 120 described later. Alternatively, the area setting unit 805 is not limited to the pull-down type, and may be configured to display an input field, which is not illustrated, for the user to manually input the number of the polishing members PM or the number of the conductive areas.

Additionally, for example, as illustrated in FIG. 7C, the area setting unit 805 may display a multiple-area input screen 112F (the area setting screen) on which multiple polishing members PM, multiple conductive areas, or both can be input by a drag-and-drop operation of the mouse 85 by the user. As an example, the multiple-area input screen 112F displays a polishing setting frame 212 indicating the size of the entire polishing area set on the mounting surface 45s. In the polishing setting frame 212, the user performs a drag-and-drop operation of a pointer 213 in conjunction with the operation of the mouse 85, thereby creating a layout of multiple divided areas according to the number and shape of the polishing members PM, the conductive area, and the like. In FIG. 7C, an example is illustrated in which three divided areas (an area A, an area B, and an area C) and one conductive area are formed on the multiple-area input screen 112F.

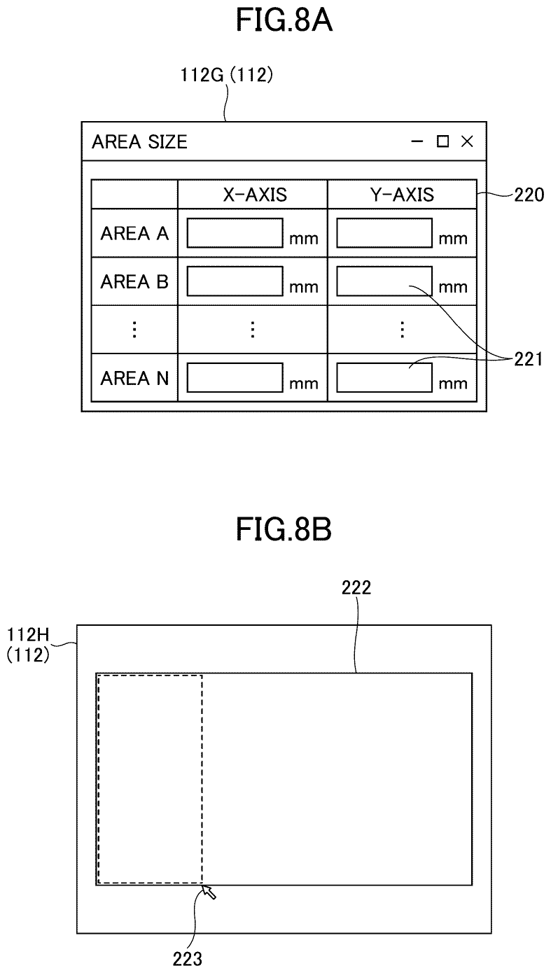

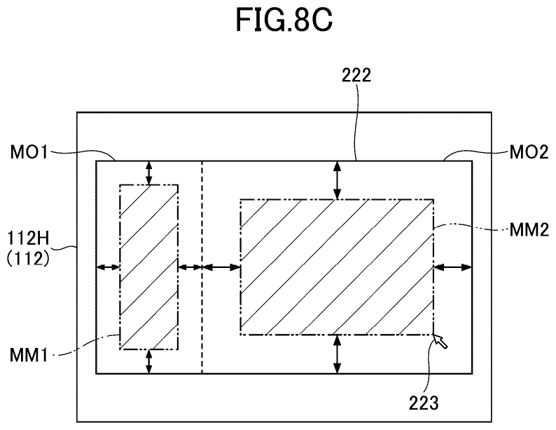

Alternatively, as illustrated in FIG. 8A, the area setting unit 805 may be configured to display a multiple-area input screen 112G (the area setting screen) including a table 220 in which the X-axis sizes and the Y-axis sizes of multiple divided areas (areas A, B, . . . , and N) can be input. The table 220 of the multiple-area input screen 112G includes input fields 221 for the user to manually input numerical values for the X-axis and the Y-axis in the multiple divided areas. When the user inputs the numerical values in the input fields 221, the divided area corresponding to the input sizes is displayed. This allows the user to smoothly dispose the polishing sheet at the same position as the polishing member PM disposed on the mounting surface 45s.

Additionally, when multiple divided areas are set, the area setting unit 805 may set the outer edge MO and the effective range MM for each of the divided areas as illustrated in FIG. 8B and FIG. 8C. For example, the area setting unit 805 displays a multiple-area input screen 112H (the area setting screen), and first, causes an outline 222 (outer edges MO1 and MO2 of the polishing member PM) of the multiple divided areas to be created by a drag-and-drop operation. Further, the area setting unit 805 performs a drag-and-drop operation inside each of the divided areas after setting the outline 222 of the multiple divided areas, thereby causing effective ranges MM1 and MM2 to be created. That is, the divided areas have the effective ranges MM1 and MM2 and margin regions, which are not used for the polishing of the probes 33, outside the effective ranges MM1 and MM2. As described, the area setting unit 805 can easily set the effective ranges MM1 and MM2 even when multiple divided areas are set.

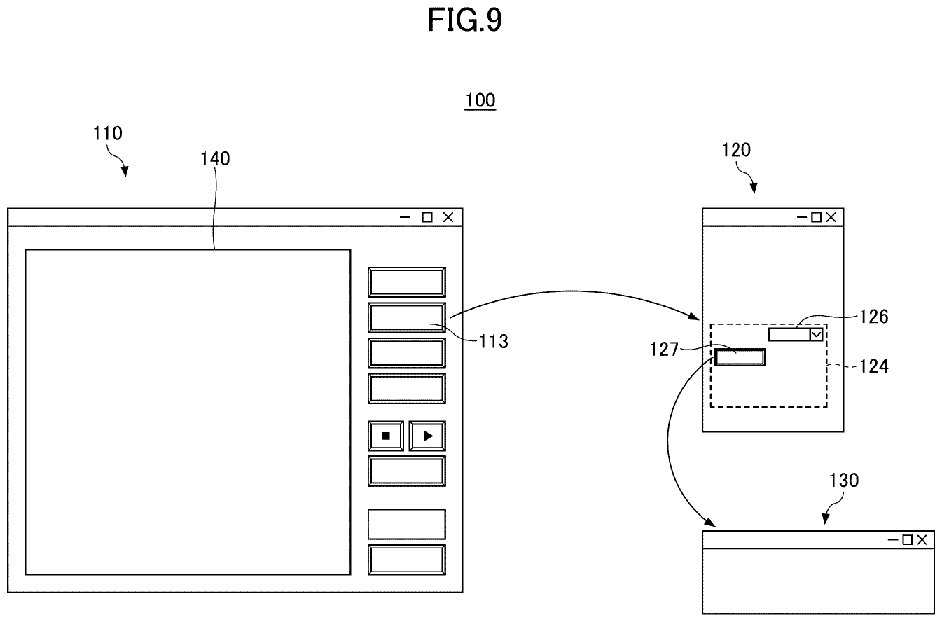

Returning to FIG. 5, the input button 113 of the area setting display group 111 of the main screen 110 is a button image for setting the size, the number, and the like of the polishing members PM and setting the operation pattern of the stage 40 during the probe polishing process. For example, as illustrated in FIG. 9, the display screen 100 displays the setting input screen 120, which is other screen information (window), in a pop-up manner in response to the input button 113 being pressed by the user. The display screen 100 allows the user to input various information related to the polishing content of the probe polishing process through the setting input screen 120.

Additionally, the setting input screen 120 includes a pattern setting item group 124 for setting an operation pattern of the probe polishing process. For example, the pattern setting item group 124 includes a setting button 127, and in response to the setting button 127 being pressed by the user, a pattern setting screen 130, which is other screen information, is displayed in a pop-up manner. The pattern setting screen 130 allows the user to set various information related to the operation pattern.

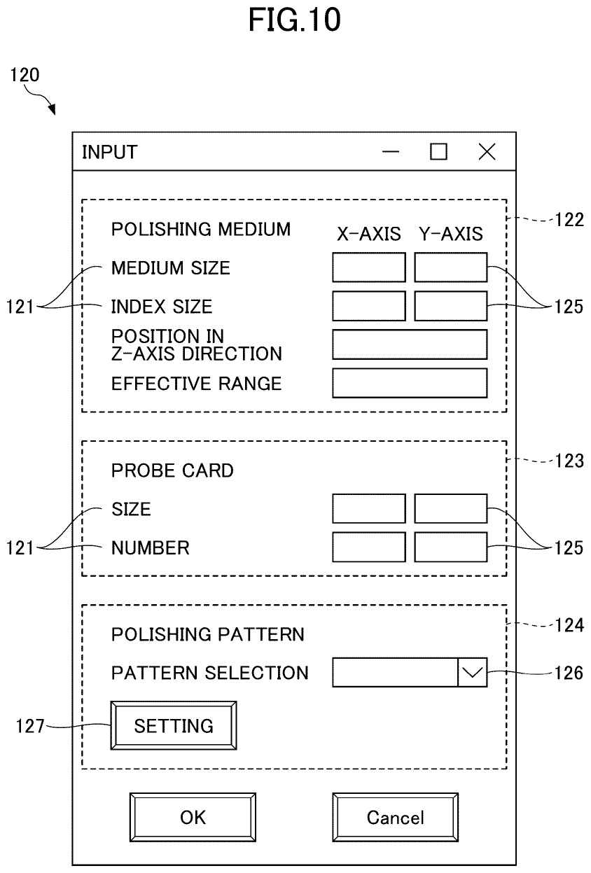

As illustrated in FIG. 10, the setting input screen 120 includes multiple types of setting items 121, such as the size of the polishing member PM, and multiple input fields 125 arranged in the horizontal direction of the setting items 121 for the user to input. The multiple types of setting items 121 are divided into a setting item group 122 of the polishing member PM, a setting item group 123 of the probe card 32, and the pattern setting item group 124 described above.

Examples of the setting item group 122 of the polishing member PM include a medium size (the size of the polishing member PM), an index size, a position in the Z-axis direction, an effective range, and the like. The medium size can be basically set automatically by pressing the polishing medium selection button 112 described above (see FIG. 5), but the user can also input the medium size on the setting input screen 120. Therefore, the setting input screen 120 is also one area setting screen for setting a polishing area. Here, although the input field 125 in which a numerical value can be input is illustrated in FIG. 10, the screens of FIG. 6A to FIG. 9C described above may be displayed selectively or in an appropriate order instead of the input field 125 or the like.

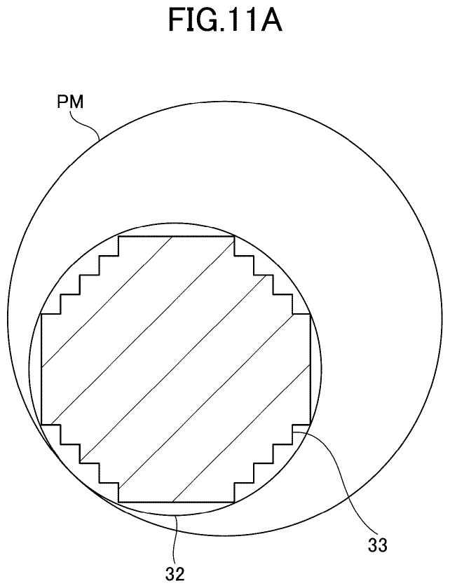

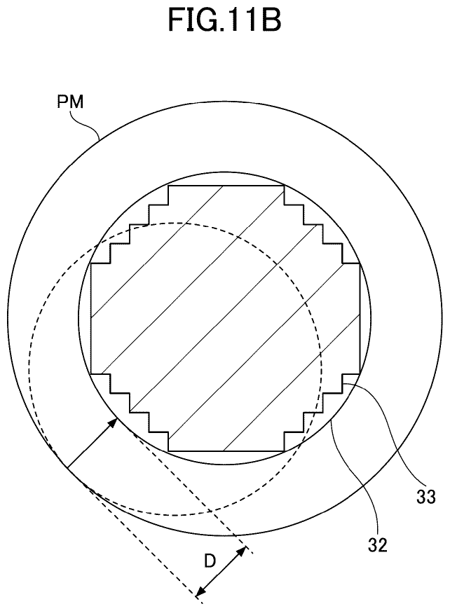

The index size of the setting item group 122 of the polishing member PM is a numerical value indicating a shift amount (an index amount) between a target position (a new surface that is not used for polishing) on the polishing member PM disposed on the mounting surface 45s and the probe 33. The polishing member PM is suitably disposed on the mounting surface 45s of the stage 40 by the user. Therefore, as illustrated in FIG. 11A, when the index amount is not set, the probe polishing process is performed in a state where the target position on the polishing member PM does not match the probe 33 of the probe card 32. The setting item 121 for the index size allows the user who has set the polishing member PM on the mounting surface 45s to input an index amount. With this, the test device 10 can move the polishing member PM based on the index amount and bring the probe 33 into contact with a new surface of the polishing member PM to perform the polishing.

Specifically, the test device 10 in which the polishing content of the probe polishing process is set based on the setting information SI controls the movement position of the stage 40 based on the set index amount, and adjusts the relative position of the polishing member PM with respect to the probes 33 of the probe card 32. For example, as illustrated in FIG. 11B, the test device 10 can make the center of the polishing member PM match the center of the probes 33 of the probe card 32 based on an index amount D (a vector obtained by combining the index of the X-axis and the index of the Y-axis).

Returning to FIG. 10, the position in the Z-axis direction in the setting item group 122 of the polishing member PM is an item for setting the contact state in the Z-axis direction between the probes 33 and the polishing member PM during the probe polishing process. During the probe polishing process, the test device 10 raises the stage 40 so that the probes 33 just barely come into contact with the surface of the polishing member PM. The area setting unit 805 can change the position of the polishing member PM in the Z-axis direction (overdrive), and thus can allow the user to adjust the contact pressure between the polishing member PM and the probes 33, the bending degree of the probes 33, and the like during the probe polishing process.

Additionally, the input field 125 of the effective range in the setting item group 122 of the polishing member PM of FIG. 10 is configured so that the user can input the effective range even in the setting input screen 120, similar to the setting of the effective range MM described above (refer to FIG. 6C and FIG. 8C).

With respect to the above, the setting item group 123 of the probe card 32 includes setting items such as a die size and a die number. The die size is an interval between the semiconductor devices (DUTs) of the wafer W, and is set so that the probes 33 come into contact with the semiconductor devices. The die number is the number of semiconductor devices that can be in contact with the probes 33. Here, the die size and the die number may be automatically set by the setting computer 80 by inputting the identification number of the probe card.

The pattern setting item group 124 operates the pattern setting unit 806 based on the user's operation to set the operation pattern of the stage 40 including the polishing member PM during the probe polishing process. The pattern setting item group 124 of the setting input screen 120 includes a pull-down type pattern selection button 126 for selecting an operation pattern, the setting button 127 for displaying the pattern setting screen 130 described above, and the like. Next, the setting of the operation pattern to be used during the probe polishing process will be described in detail.

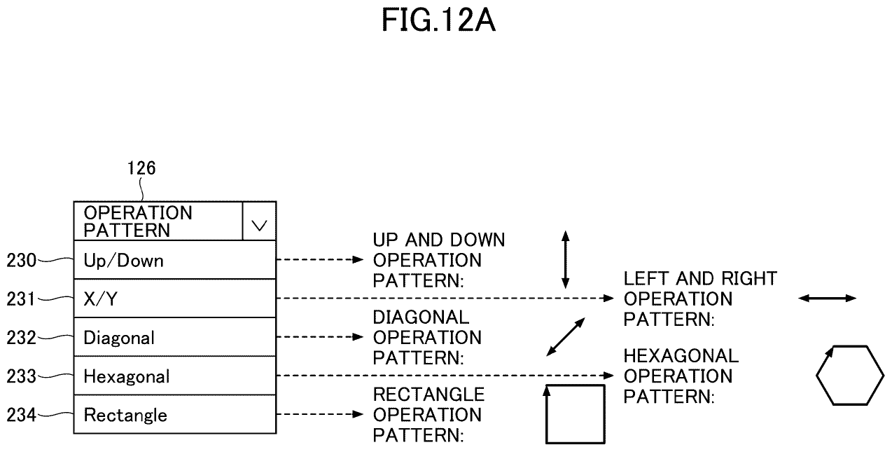

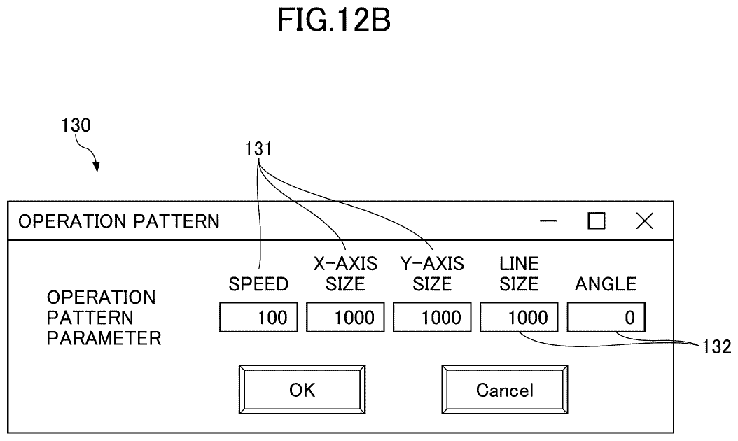

As illustrated in FIG. 12A, the pattern selection button 126 of the pattern setting item group 124 allows the user to select an operation pattern of the stage 40 on which the polishing member PM is disposed during the probe polishing process. The options of the pattern selection button 126 include an up-and-down option 230, a left-and-right option 231, a diagonal option 232, a hexagonal option 233, and a rectangular option 234. The up-and-down option 230 sets an up-and-down operation pattern (a first direction pattern) in which the polishing member PM reciprocates in the up and down direction (the X-axis direction). The left-and-right option 231 sets a left-and-right operation pattern (a second direction pattern) in which the polishing member PM reciprocates in the left and right direction (the Y-axis direction). The diagonal option 232 sets a diagonal operation pattern (a diagonal direction pattern) in which the polishing member PM reciprocates in a direction diagonal to the X axis and the Y axis. The hexagonal option 233 sets a hexagonal operation pattern (a circumferential direction pattern) in which the polishing member PM circumferentially moves to draw a hexagon. The rectangular option 234 sets a square operation pattern (a circumferential direction pattern) in which the polishing member PM circumferentially moves to draw a square.

As illustrated in FIG. 12B, the pattern setting screen 130 includes multiple types of parameters 131 of the operation pattern of the polishing member PM and multiple input fields 132 arranged below the respective parameters 131 and used for the user's input. Examples of the multiple types of parameters 131 include the speed, the X-axis size, the Y-axis size, the line size, the angle, and the like.

The input field 132 for the speed is a field for setting the movement speed of the operation pattern selected by the pattern selection button 126. The input field 132 for the X-axis size is a field for setting the movement amount in the X-axis direction in the movement pattern selected by the pattern selection button 126. Similarly, the input field 132 for the Y-axis size is a field for setting the movement amount in the Y-axis direction in the movement pattern selected by the pattern selection button 126. The input field 132 for the line size is a field for setting the length (the length of the entire movement amount) of the trajectory of the movement pattern selected by the pattern selection button 126. The input field 132 for the angle is a field for setting an angle inclined with respect to the X axis or the Y axis in the operation pattern set by the pattern selection button 126. As described, the pattern setting unit 806 enables the user to set multiple types of parameters of the operation pattern, and thus, the polishing member PM that is in contact with the probes 33 can be used for the polishing in accordance with a desired operation pattern during the probe polishing process.

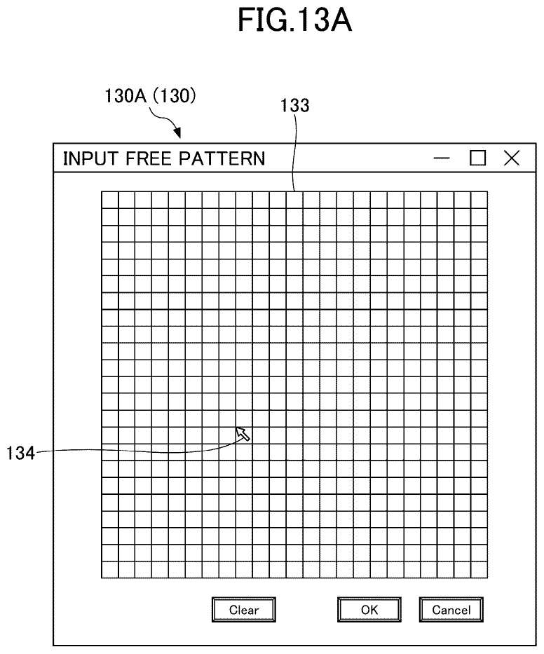

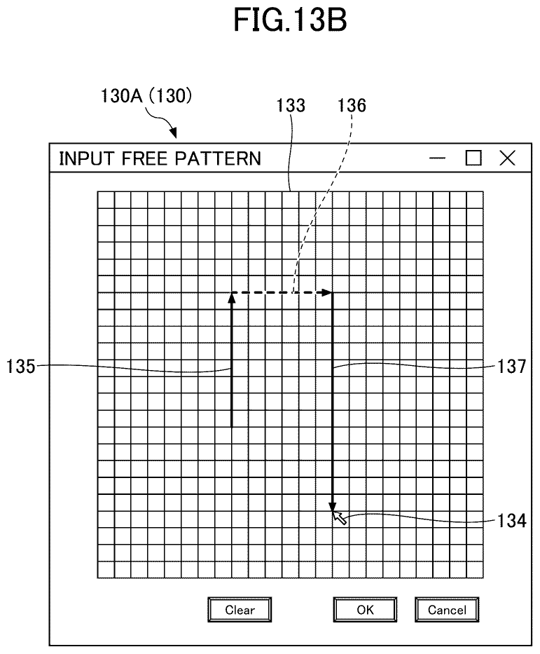

Here, the setting of the operation pattern of the polishing member PM is not limited to the setting via the pattern selection button 126 or the pattern setting screen 130, and various setting methods can be adopted. For example, the pattern setting unit 806 may be configured so that a free pattern setting screen 130A as illustrated in FIG. 13A and FIG. 13B is displayed, and the user may manually draw the operation pattern on the free pattern setting screen 130A. With this, in the probe polishing process, the test device 10 can cause the polishing member PM to operate in accordance with the movement pattern drawn by the user.

Specifically, the free pattern setting screen 130A displays a handwriting portion 133 having a grid on substantially the entire free pattern setting screen 130A. On the free pattern setting screen 130A, for example, the user places a pointer 134 on a selected grid point and performs a drag-and-drop operation to create an operation pattern of the polishing member PM. Here, the handwriting portion 133 may allow the user to draw a free line without being bound by the grid points.

As an example, the user places the pointer 134 at the polishing start position, moves the pointer 134 in a predetermined direction (upward in FIG. 13B) while clicking the mouse 85, and drops at a desired position. With this, a trajectory 135 in which the polishing member PM moves upward can be set. Additionally, the pattern setting unit 806 can set a non-contact operation in which the polishing member PM and each of the probes 33 are in a non-contact state (a separated state) and move in the operation pattern. For example, after drawing the trajectory of the operation pattern and dropping, the pointer 134 is moved to a desired position and a drag-and-drop operation of the mouse 85 is performed again. With this, a range from the dropping to the dragging again can be set as a trajectory 136 of the non-contact operation in which the polishing member PM is separated from each of the probes 33. Further, the user can draw a trajectory 137 of the movement pattern by performing a drag-and-drop operation again.

As described above, by freely designing the operation pattern of the polishing member PM by using the handwriting portion 133, the control device 90 in which the polishing content has been set can operate the polishing member PM in accordance with the operation pattern of the user during the probe polishing process. With this, the probes 33 can be ground as desired by the user.

The polishing content of the probe polishing process is completed by setting the area and the operation pattern. The setting computer 80 can perform simulation for the set polishing content before transmitting the setting information SI of the polishing content to the test device 10. The simulation unit 807 illustrated in FIG. 4 performs a polishing simulation based on the set polishing content, based on an operation of executing the simulation by the user. Specifically, the user operates the simulation display group 141 of the main screen 110 illustrated in FIG. 5.

The simulation display group 141 includes a start button 142 for starting the simulation, an execution status graph 143 indicating an execution status of the simulation, a reset button 144, and a stop and play button 145. When the user presses the start button 142, the simulation unit 807 starts the simulation according to the set polishing content.

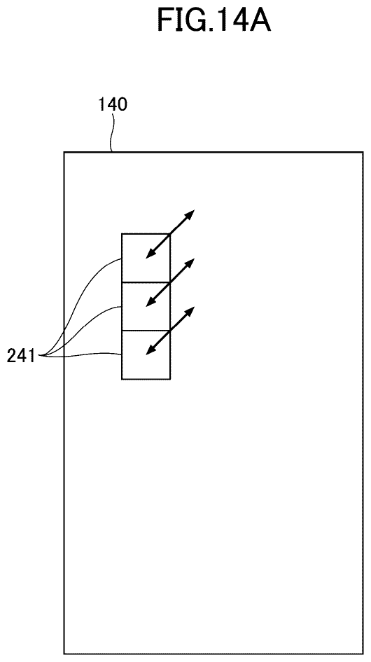

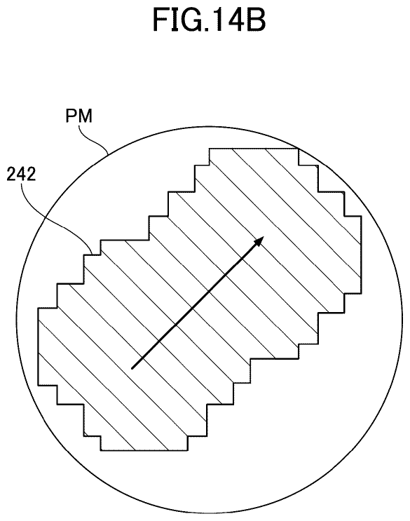

As illustrated in FIG. 14A, in the simulation by the simulation unit 807, multiple frames 241 are formed in units corresponding to the semiconductor devices of the wafer W to be tested by the probe 33, and the multiple frames 241 move in accordance with the set operation pattern. Additionally, in the probe polishing process, an operation of changing the position in the polishing member PM where the probes 33 come into contact is performed, while the polishing is performed in accordance with the set operation pattern. Therefore, the simulation unit 807 calculates a movement region of the multiple frames 241 that move relative to the polishing member PM in accordance with the operation pattern corresponding to the polishing content and the movement of the position of the polishing member PM.

Then, the simulation unit 807 displays the trajectory of the calculated movement region on the simulation display screen 140 in real time. With this, as illustrated in FIG. 14B, the simulation unit 807 can allow the user to visually recognize, satisfactorily, the movement region of the multiple frames 241, which is a use range 242 to be actually used in the polishing member PM.

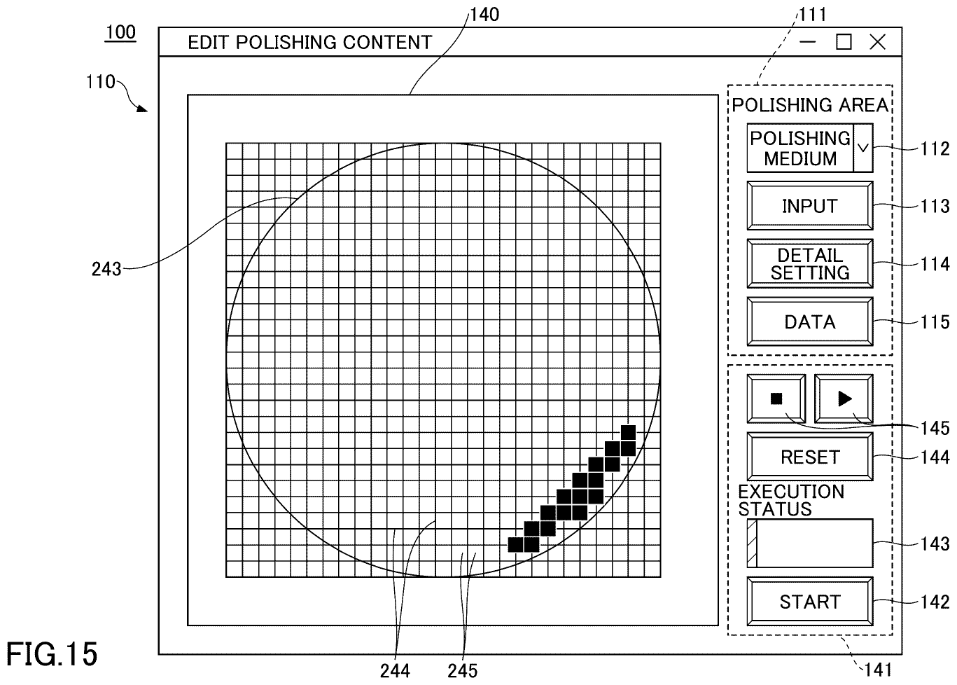

More specifically, as illustrated in FIG. 15, the simulation display screen 140 displays, in the simulation, a polishing area frame 243 indicating the polishing member PM in advance, and forms multiple grid lines 244 corresponding to the unit of the dies (the semiconductor devices of the wafer W) for the probes 33. The inside of the polishing area frame 243 is in a display form in which multiple grid areas 245 are arranged in a matrix by the multiple grid lines 244. The simulation unit 807 fills the grid area 245 with color in accordance with the trajectory calculated by the simulation for the movement area of the multiple frames 241 (see FIG. 14A) based on the operation pattern according to the polishing content and the movement of the position of the polishing member PM. With this, the simulation display screen 140 can display, in real time, the range to be actually used in the polishing member PM.

For example, immediately after the simulation is started, a small number of grid areas 245 are filled as portions where the polishing member PM polishes the probes 33 first. Additionally, during the simulation, the execution status graph 143 displays the progress status of the simulation by a bar extending in the horizontal direction, and the bar is short immediately after the simulation is started.

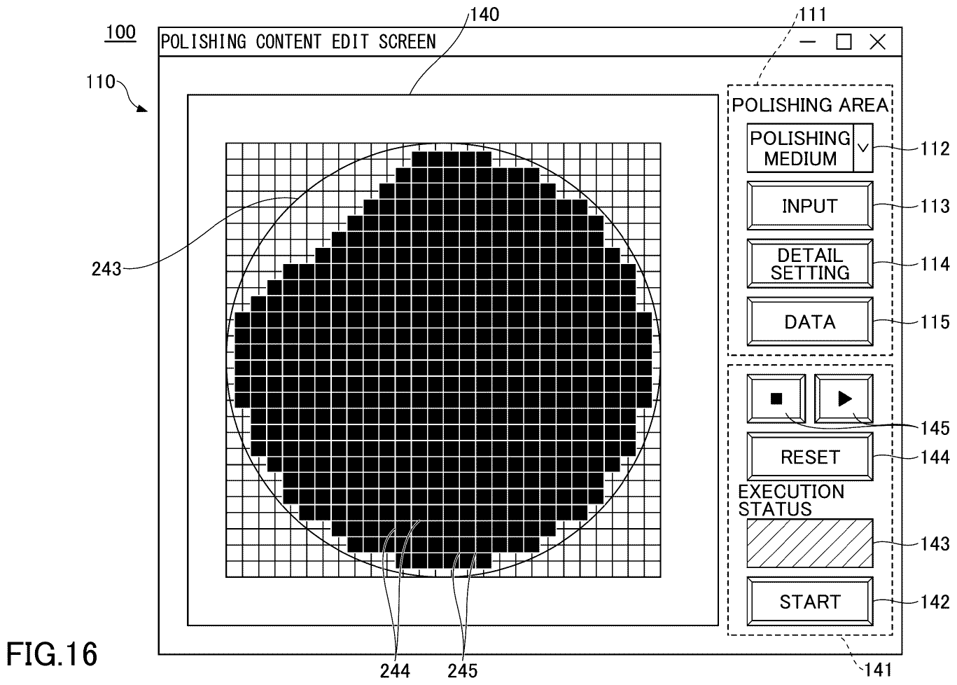

As the simulation progresses, as illustrated in FIG. 16, the probes 33 come into contact with the entire polishing member PM as the polishing member PM moves. Therefore, many grid areas 245 are filled. When the simulation is finished, the simulation display screen 140 can indicate the use range 242 (the range where the probes 33 are in contact) in which the polishing member PM is used for polishing, by a range of the multiple grid areas 245 that are filled. Here, as described above, the polishing member PM disposed on the stage 40 changes its position while repeating the reciprocating movement based on the set operation pattern. Therefore, the simulation display screen 140 may change the filling state of each of the grid areas 245 according to the contact frequency with respect to the polishing member PM. For example, the filling color may be displayed to be lighter when the contact frequency is low, and the filling color may be displayed to be darker as the contact frequency increases.

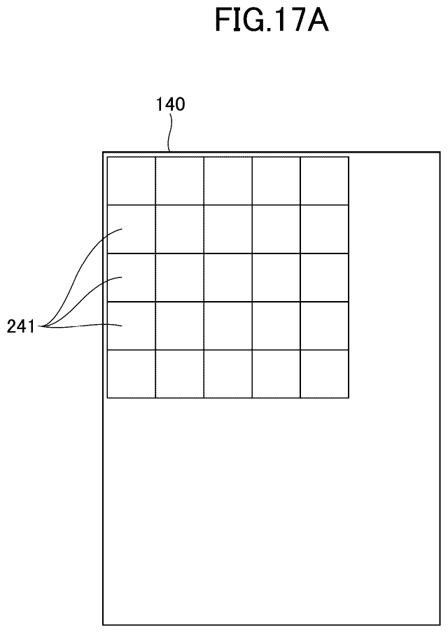

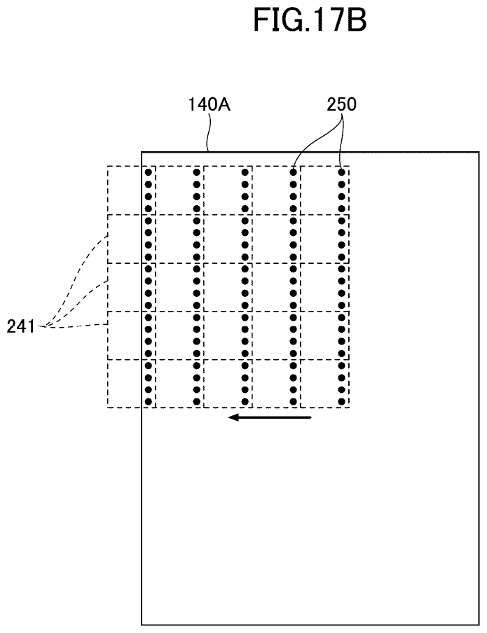

As described above, the simulation unit 807 forms, in units corresponding to the semiconductor devices of the wafer W, the multiple frames 241 that move relative to the polishing member PM in the simulation (see FIG. 17A). However, each of the frames 241 has a size larger than the probe 33 that is actually ground, and when the movement of each of the frames 241 is simulated, the trajectory is drawn in a region larger than a trajectory in which each of the probes 33 is ground.

Therefore, as illustrated in FIG. 17B, the simulation unit 807 may calculate a trajectory corresponding to the probes 33 instead of the frames 241, which are in units corresponding to the semiconductor devices of the wafer W. For example, instead of the frames 241, multiple plots 250 corresponding to the respective probes 33 are arranged on a simulation display screen 140A. The simulation unit 807 calculates a trajectory of the plots 250 in the simulation. With this, the use range of the polishing member PM is different between the case where the simulation is performed by arranging the multiple frames 241 and the case where the simulation is performed by arranging the multiple plots 250.

That is, when the multiple frames 241 are used as illustrated in FIG. 17A, even if a frame 241 is moved to the outer edge of the polishing member PM, the actual probe 33 may be positioned inside the outer edge of the polishing member PM. In contrast, as illustrated in FIG. 17B, when the multiple plots 250 are used, the multiple plots 250 are moved to the vicinity of the outer edge of the polishing member PM, and the simulation can be performed from this position. With this, the setting computer 80 can generate the setting information SI used for polishing up to the vicinity of the outer edge of the polishing member PM, and the polishing member PM can be efficiently used by using the setting information SI.

Additionally, the simulation unit 807 may be configured to determine the presence or absence of abnormality in the polishing content set by the user based on the use state of the polishing member PM calculated in the simulation. For example, in the simulation, when the use range 242 used for the polishing exceeds the set polishing area, it is determined that the polishing content is abnormal. Alternatively, the simulation unit 807 may determine that the polishing content is abnormal when the use range 242 is excessively concentrated on a partial region of the polishing member PM. This is because, when the use range 242 is too concentrated, the life of the polishing member PM is shortened.

Additionally, the user may stop the simulation at an appropriate timing by operating the stop and play button 145 while viewing the simulation display screen 140 during the execution of the simulation, or may restart the simulation after the stop. Additionally, for example, when the user himself/herself determines that there is abnormality during the execution of the simulation, the user may stop the simulation by operating the reset button 144.

Then, the user can reset the polishing area or reset the operation pattern by operating the area setting display group 111 based on the result or process of the simulation. By performing the simulation again with the reset polishing content, the polishing content can be adjusted to polishing content that is more desirable to the user. That is, the setting computer 80 may repeat the setting of the polishing area, the setting of the operation pattern, and the simulation many times. As described, the setting computer 80, as an external device separate from the test device 10, can set the polishing content of the probe polishing process as a user-specific setting and set the polishing content (recipe) in the test device 10.

Here, the setting computer 80 can also read (import) data of polishing content created in the past and perform editing using the past polishing content. For example, by pressing the data button 115 on the main screen 110 illustrated in FIG. 5, a screen (not illustrated) for accessing a folder storing the data of the past polishing content is displayed, and this screen allows the user to select the past polishing content. Alternatively, the display screen generation unit 803 may display a list of simplified versions of multiple instances of past polishing content based on the operation of the data button 115 and allow the user to select the polishing content.

Additionally, in the above embodiments, the test device 10 including the single tester 30 and the single stage 40 has been described. However, the configuration thereof is not particularly limited as long as the test device can perform the probe polishing process, and for example, a test device (not illustrated) including multiple testers 30 may be used. Also, in this case, the test device can perform the probe polishing process on each of the probes 33 of the probe card 32 mounted on each of the testers 30 according to the polishing content by transmitting, to the test device, the polishing content set in the setting computer 80. Alternatively, the processing system 1 may be configured so that the processing system 1 includes a dedicated device configured to perform only the probe polishing process of each of the probes 33, and the setting computer 80 sets the polishing content in the dedicated device.

The technical ideas and effects of the present disclosure described in the above embodiments will be described below.

[1]: The information processing device (the setting computer 80) for setting the polishing content of the probes 33 configured to contact the devices under test includes the area setting unit 805 configured to set the polishing area in the polishing member PM for polishing the probes 33, the pattern setting unit 806 configured to set the operation pattern to be used during the polishing of the probes 33, and the simulation unit 807 configured to calculate the relative trajectory between the polishing member PM and the probes 33 based on the set polishing area and the set operation pattern.

According to the above, the information processing device (the setting computer 80) can set the polishing content easily and in detail in the probe polishing process of polishing the probes 33. In particular, the information processing device prepared outside the control device 90 sets the polishing content of the probe polishing process, so that an increase in work hours due to a restriction on a setting method for each device or development for each device can be suppressed, and a design with a high degree of freedom can be achieved. That is, the information processing device can standardize the setting of the polishing content of the probes, and can reduce work hours.

[2]: The information processing device (the setting computer 80) according to [1] includes the stage 40 for moving the polishing member PM in the three-dimensional directions and the control device configured to control the operation of the stage 40, is connected to the test device 10 that actually polishes the probes 33, and transmits, to the test device 10, the setting information SI set by the area setting unit 805 and the pattern setting unit 806. With this, the information processing device sets the polishing content of the probe polishing process for each of the multiple test devices 10, and then transmits the setting information of the polishing content to the test device 10, so that the test device 10 can smoothly perform the probe polishing process of polishing the probes.

[3]: In the information processing device (the setting computer 80) according to [1] or [2], the area setting unit 805 can set multiple divided areas obtained by dividing the polishing area. With this, even when the probes are ground using multiple types of polishing members PM, the areas of the multiple polishing members PM can be set in detail.

[4]: In the information processing device (the setting computer 80) according to any one of [1] to [3], the area setting unit 805 can set, inside the polishing area, the effective range of the polishing member PM that is effective for the polishing of the probes 33. With this, the effective range of the polishing member PM can be appropriately set, and the entire polishing member PM can be effectively used in the probe polishing process.

[5]: In the information processing device (the setting computer 80) according to any one of [1] to [4], the area setting unit 805 can set the polishing area by the drag-and-drop operation at the display and input device 82 connected to the information processing device. With this, the information processing device can easily set the polishing area.

[6]: In the information processing device (the setting computer 80) according to any one of [1] to [5], the pattern setting unit 806 allows the user to select multiple types of operation patterns. With this, the information processing device can easily set the operation pattern of the polishing process.

[7]: In the information processing device (the setting computer 80) according to [6], the multiple types of operation patterns include a first direction pattern (an up-and-down operation pattern) in which the polishing member PM reciprocates in a first direction, a second direction pattern (a left-and-right operation pattern) in which the polishing member PM reciprocates in a second direction orthogonal to the first direction, a diagonal direction pattern in which the polishing member PM reciprocates in a direction diagonal to the first direction and the second direction, and a circumferential direction pattern (a hexagonal operation pattern or a rectangular operation pattern) in which the polishing member PM circumferentially moves along a polygonal path. With this, the information processing device can selectively perform various operation patterns in the probe polishing process.

[8]: In the information processing device (the setting computer 80) according to any one of [1] to [7], the pattern setting unit 806 can set the operation pattern by the drag-and-drop operation at the display and input device 82 connected to the information processing device. With this, the information processing device can easily set the operation pattern desired by the user.

[9]: In the information processing device (the setting computer 80) according to any one of [1] to [8], the simulation unit 807 forms the multiple frames 241 corresponding to the devices under test, calculates the trajectory of the multiple frames 241 that relatively move in accordance with the operation of the polishing member PM, and displays the calculated trajectory of the multiple frames 241 on the display and input device 82 connected to the information processing device. With this, the user who visually recognizes the result of the simulation can easily grasp the portion of the polishing member PM to be actually used for the polishing.

[10]: In the information processing device (the setting computer 80) according to any one of [1] to [8], the simulation unit 807 forms the multiple plots 250 corresponding to the multiple probes 33, calculates the trajectory of the multiple plots 250 that relatively move in accordance with the operation of the polishing member PM, and displays the calculated trajectory of the multiple plots 250 on the display and input device 82 connected to the information processing device. With this, the information processing device can perform the simulation corresponding to the polishing of the multiple probes. Additionally, in the setting, the range where the polishing member PM is in contact with the probes can be widened, and the polishing member PM can be effectively used.

[11]: The display and input device 82 includes the display screen 100 for displaying the polishing content of the probes 33 configured to contact the devices under test and is configured to set the polishing content by the user's operation on the display screen 100. The display screen 100 includes the area setting screen (the setting input screen 120) for setting the polishing area in the polishing member PM for polishing the probes 33, the pattern setting screen 130 for setting the operation pattern to be used during the polishing of the probes 33, and the simulation display screen 140 for displaying the relative trajectory between the polishing member PM and the probes 33, the relative trajectory being calculated based on the set polishing area and the set operation pattern.

[12]: The program 87p sets the polishing content of the probes 33 configured to contact the devices under test, and the program causes the information processing device (the setting computer 80) to perform: setting the polishing area in the polishing member PM for polishing the probes 33; setting the operation pattern to be used during the polishing of the probes 33; and calculating the relative trajectory between the polishing member PM and the probes 33 based on the set polishing area and the set operation pattern.

According to one aspect, the setting of the polishing content of the probe is standardized, and thus work hours can be reduced.

The information processing device, the display and input device, and the program according to the embodiments disclosed herein are illustrative and not restrictive in all respects. The embodiments can be modified and improved in various forms without departing from the scope and spirit of the appended claims. The matters described in the above embodiments can also take other configurations as long as there is no contradiction, and can be combined with each other as long as there is no contradiction.

What is claimed is:

1. An information processing device for setting polishing content of probes configured to contact devices under test, comprising:
a processor; and
a memory storing program instructions that cause the processor to:
set a polishing area in a polishing member configured to polish the probes;
set an operation pattern to be used during the polishing of the probes; and
calculate a relative trajectory between the polishing member and the probes based on the set polishing area and the set operation pattern.

2. The information processing device as claimed in claim 1, further comprising:
a stage for moving the polishing member in three-dimensional directions; and
a control device configured to control an operation of the stage,
wherein the information processing device is connected to a test device that actually polishes the probes, and transmits the set polishing area and the set operation pattern to the test device.

3. The information processing device as claimed in claim 1, wherein the program instructions cause the processor to set a plurality of divided areas obtained by dividing the polishing area.

4. The information processing device as claimed in claim 1, wherein the program instructions cause the processor to set an effective range of the polishing member to be inside the polishing area, the effective range being effective for polishing the probes.

5. The information processing device as claimed in claim 1, wherein the program instructions cause the processor to allow a user to set the polishing area by a drag-and-drop operation at a display and input device connected to the information processing device.

6. The information processing device as claimed in claim 1, wherein the program instructions cause the processor to allow a user to select a plurality of types of said operation patterns.

7. The information processing device as claimed in claim 6, wherein the plurality of types of operation patterns include a first direction pattern in which the polishing member reciprocates in a first direction, a second direction pattern in which the polishing member reciprocates in a second direction orthogonal to the first direction, a diagonal direction pattern in which the polishing member reciprocates in a direction diagonal to the first direction and the second direction, and a circumferential direction pattern in which the polishing member circumferentially moves along a polygonal path.

8. The information processing device as claimed in claim 1, wherein the program instructions cause the processor to allow a user to set the operation pattern by a drag-and-drop operation at a display and input device connected to the information processing device.

9. The information processing device as claimed in claim 1, wherein the program instructions cause the processor to form a plurality of frames corresponding to the devices under test, calculates a trajectory of the plurality of frames that relatively move in accordance with the operation of the polishing member, and displays the calculated trajectory of the plurality of frames on a display and input device connected to the information processing device.

10. The information processing device as claimed in claim 1, wherein the program instructions cause the processor to form a plurality of plots corresponding to the probes, calculate a trajectory of the plurality of plots that relatively move in accordance with the operation of the polishing member, and display the calculated trajectory of the plurality of plots on a display and input device connected to the information processing device.

11. A display and input device comprising a display screen for displaying polishing content of probes configured to contact devices under test, the display and input device being configured to set the polishing content by a user's operation on the display screen,
wherein the display screen includes:
an area setting screen for setting a polishing area in a polishing member configured to polish the probes;
a pattern setting screen for setting an operation pattern to be used during the polishing of the probes; and
a simulation display screen for displaying a relative trajectory between the polishing member and the probes, the relative trajectory being calculated based on the set polishing area and the set operation pattern.

12. A non-transitory computer-readable recording medium having stored therein a program for setting polishing content of probes configured to contact devices under test, the program causing an information processing device to perform:
setting a polishing area in a polishing member configured to polish the probes;
setting an operation pattern to be used during the polishing of the probes; and
calculating a relative trajectory between the polishing member and the probes based on the set polishing area and the set operation pattern.
